(19) United States
(12) Patent Application Publication
(10) Pub. No.: US 2025/0379070 A1
(43) Pub. Date: Dec. 11, 2025

(54) SUBSTRATE PROCESSING APPARATUS AND SUBSTRATE PROCESSING METHOD

(71) Applicant: Tokyo Electron Limited, Tokyo (JP)

(72) Inventors: Masataka GOSHO, Koshi City (JP); Reijiro YAMANAKA, Tokyo (JP); Tomofumi EMURA, Koshi City (JP)

(73) Assignee: Tokyo Electron Limited, Tokyo (JP)

(21) Appl. No.: 19/227,685

(22) Filed: Jun. 4, 2025

(30) Foreign Application Priority Data
Jun. 6, 2024 (JP) 2024-092245

(51) Int. Cl. H01L 21/67; H01L 21/02

(52) U.S. Cl. CPC H01L 21/67034; H01L 21/02101; H01L 21/67248

(57) ABSTRACT

A substrate processing apparatus includes a processing chamber; a discharge line; a density detector; a temperature detector; a pressure detector; and processing circuitry. The density detector, the temperature detector, and the pressure detector are configured to detect a density, a temperature, and a pressure, respectively, of a fluid flowing through the discharge line. The processing circuitry is configured to acquire a mixed fluid density and a reference density, which is a density of the supercritical fluid; calculate a correction value based on detection results from the temperature detector and the pressure detector; correct the reference density based on the correction value; and calculate a density difference between the mixed fluid density and the corrected reference density.

### CROSS-REFERENCE TO RELATED APPLICATION

This application claims the benefit of Japanese Patent Application No. 2024-092245 filed on Jun. 6, 2024, the entire disclosure of which is incorporated herein by reference.

### TECHNICAL FIELD

The exemplary embodiments described herein pertain generally to a substrate processing apparatus and a substrate processing method.

### BACKGROUND

In the related art, there has been known a supercritical drying processing to dry a substrate by bringing a wafer with a surface wet by a liquid into contact with a supercritical fluid and replacing the liquid with the supercritical fluid.

For example, a substrate processing apparatus disclosed in Patent Document 1 obtains a density profile in each of a dry state where a liquid to be replaced is not present in a chamber and a wet state where the liquid to be replaced is present in the chamber by supplying and discharging a supercritical fluid and compares the obtained density profiles. The substrate processing apparatus determines a time at which the densities obtained in the respective states become substantially equal to each other after the density in the wet state becomes larger than the density in the dry state as a termination time of the replacement of the liquid to be replaced with the supercritical fluid.

### PRIOR ART DOCUMENT

Patent Document 1: Japanese Patent Laid-open Publication No. 2022-115405

### SUMMARY

In one exemplary embodiment, a substrate processing apparatus includes a processing chamber; a discharge line; a density detector; a temperature detector; a pressure detector; and processing circuitry. The processing chamber is configured to perform a drying processing on a substrate by supplying a supercritical fluid into the processing chamber and replacing a drying liquid accumulated on the substrate with the supercritical fluid. The discharge line is configured to discharge a fluid from an inside of the processing chamber, the fluid being the supercritical fluid or a mixed fluid containing the supercritical fluid and the drying liquid. The density detector is configured to detect a density of the fluid flowing through the discharge line. The temperature detector is configured to detect a temperature of the fluid flowing through the discharge line. The pressure detector is configured to detect a pressure of the fluid flowing through the discharge line. The processing circuitry is configured to acquire a mixed fluid density, which is a density of the mixed fluid, detected by the density detector; acquire a reference density, which is a density of the supercritical fluid, detected by the density detector; calculate a correction value for correcting the reference density based on detection results from the temperature detector and the pressure detector; correct the reference density based on the correction value; and calculate a density difference, which is a difference between the mixed fluid density and the corrected reference density.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

In the detailed description that follows, exemplary embodiments are described as illustrations only since various changes and modifications will become apparent to those skilled in the art from the following detailed description. The use of the same reference numerals in different figures indicates similar or identical items.

FIG. 1 is a top view of a substrate processing system according to a present exemplary embodiment;

FIG. 2 is a side view of the substrate processing system according to the present exemplary embodiment;

FIG. 3 is a flowchart illustrating a sequence of a series of substrate processings performed in the substrate processing system according to the present exemplary embodiment;

FIG. 4 is a schematic diagram showing a sequence of transferring a wafer;

FIG. 5 is a schematic diagram illustrating an example configuration of a liquid processing unit according to the present exemplary embodiment;

FIG. 6 is a schematic diagram illustrating an example configuration of a drying unit according to the present exemplary embodiment;

FIG. 7 is a schematic diagram illustrating an example pipe arrangement of the drying unit according to the present exemplary embodiment;

FIG. 8 is a flowchart illustrating a sequence of supercritical drying processings performed in the substrate processing system according to the present exemplary embodiment;

FIG. 9 is a schematic diagram illustrating an example configuration of a discharge line according to the present exemplary embodiment;

FIG. 10 illustrates an example configuration of a control device according to the present exemplary embodiment as functional blocks;

FIG. 11 shows an example of time-dependent changes in a mixed fluid density and a reference density;

FIG. 12 shows an example of time-dependent changes in first temperature, first pressure, second temperature, and second pressure;

FIG. 13 shows an example of a relationship of density, pressure, and temperature of a supercritical fluid;

FIG. 14 shows an example of time-dependent changes in first density and second density;

FIG. 15 shows an example of time-dependent changes in mixed fluid density, reference density, and corrected reference density;

FIG. 16 shows an example of time-dependent changes in density difference between the mixed fluid density and the corrected reference density;

FIG. 17 shows a first comparative example of the density difference between the mixed fluid density and the reference density;

FIG. 18 shows a second comparative example of the density difference between the mixed fluid density and the reference density;

FIG. 19 shows a third comparative example of the density difference between the mixed fluid density and the reference density;

FIG. 20 shows an example of data stored in a storage according to the present exemplary embodiment;

FIG. 21 is a flowchart illustrating a sequence of a series of density difference calculation processings performed in a controller according to the present exemplary embodiment;

FIG. 22 is a flowchart illustrating a sequence of determination processings performed in a suitability determiner according to the present exemplary embodiment;

FIG. 23 shows a relationship of the density difference between the mixed fluid density and the corrected reference density and a pressure in a processing chamber;

FIG. 24 is a flowchart illustrating a sequence of determination processings performed in a drying termination determiner according to the present exemplary embodiment; and

FIG. 25 is a flowchart illustrating a sequence of controlling a start timing of a decompression processing performed in the controller according to the present exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other exemplary embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, embodiments (hereinafter, referred to as “exemplary embodiments”) of a substrate processing apparatus and substrate processing method according to the present disclosure will be described in detail with reference to the accompanying drawings. Further, the present disclosure is not limited to the following exemplary embodiments. Furthermore, the exemplary embodiments can be appropriately combined as long as processing contents are not contradictory to each other. Also, in each of the exemplary embodiments described below, same parts will be assigned same reference numerals, and redundant description will be omitted.

Further, in each of the accompanying drawings, for the purpose of clear understanding, there may be used a rectangular coordinate system in which the X-axis direction, Y-axis direction and Z-axis direction which are orthogonal to one another are defined and the positive Z-axis direction is defined as a vertically upward direction.

### <Configuration of Substrate Processing System>

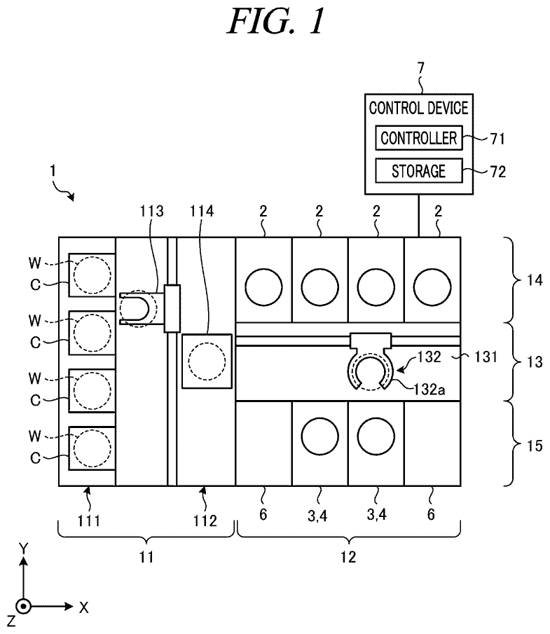

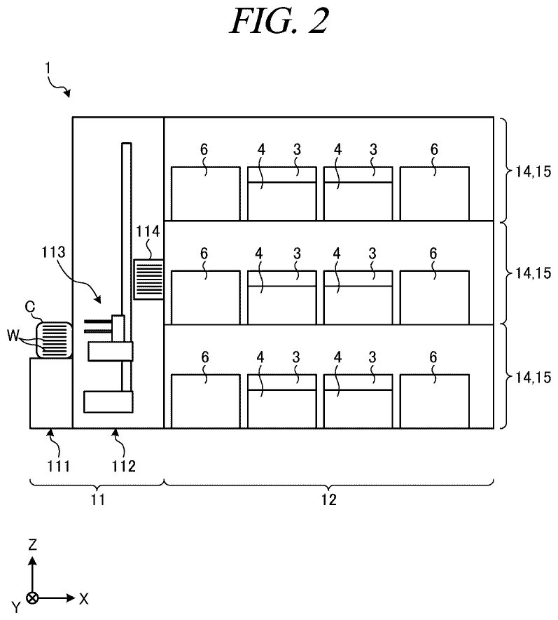

First, a configuration of a substrate processing system (an example of the substrate processing apparatus) according to the present exemplary embodiment will be described with reference to FIG. 1 and FIG. 2. FIG. 1 is a top view of a substrate processing system according to the present exemplary embodiment. FIG. 2 is a side view of the substrate processing system according to the present exemplary embodiment.

As shown in FIG. 1, a substrate processing system 1 is equipped with a carry-in/out station 11 and a processing station 12. The carry-in/out station 11 and the processing station 12 are provided adjacent to each other.

The carry-in/out station 11 is equipped with a carrier placing section 111 and a transfer section 112. In the carrier placing section 111, a plurality of carriers C is placed to accommodate a plurality of semiconductor wafers W (hereinafter, referred to as “wafers W”) horizontally.

The transfer section 112 is provided adjacent to the carrier placing section 111, and equipped with a transfer device 113 and a delivery module 114.

The transfer device 113 is equipped with a wafer holding mechanism configured to hold the wafer W. Further, the transfer device 113 is movable in a horizontal direction and a vertical direction and pivotable around a vertical axis, and transfers the wafers W between the carriers C and the delivery module 114 by the wafer holding mechanism.

The delivery module 114 is configured to temporarily place thereon the wafer W.

The processing station 12 is provided adjacent to the transfer section 112. The processing station 12 is equipped with a transfer block 13, a first processing block 14, and a second processing block 15.

The transfer block 13 is equipped with a transfer area 131 and a transfer device 132. The transfer area 131 is, for example, a rectangular parallelepiped region extending along an arrangement direction of the carry-in/out station 11 and the processing station 12 (X-axis direction). The transfer device 132 is disposed in the transfer area 131.

The transfer device 132 is equipped with a wafer holding mechanism 132a configured to hold the wafer W. Further, the transfer device 132 is movable in a horizontal direction and a vertical direction and pivotable around a vertical axis. The transfer device 132 transfers the wafer W between the delivery module 114 and the first and second processing blocks 14 and 15 by means of the wafer holding mechanism 132a.

The first processing block 14 and the second processing block 15 are disposed on both sides of the transfer area 131 to be adjacent to the transfer area 131. For example, the first processing block 14 is disposed on one side (positive side in the Y-axis direction) of the transfer area 131 in a direction (Y-axis direction) orthogonal to the arrangement direction (X-axis direction) of the carry-in/out station 11 and the processing station 12. Also, the second processing block 15 is disposed on the other side (negative side in the Y-axis direction) of the transfer area 131 in the direction (Y-axis direction) orthogonal to the arrangement direction (X-axis direction) of the carry-in/out station 11 and the processing station 12.

Further, as shown in FIG. 2, a plurality of first processing blocks 14 and a plurality of second processing blocks 15 may be disposed in a plurality of stages along the vertical direction. In the present exemplary embodiment, the plurality of first processing blocks 14 is disposed in three stages and the plurality of second processing blocks 15 is disposed in three stages. However, the number of the stages of the plurality of first processing blocks 14 and the plurality of second processing blocks 15 is not limited to three.

As described above, in the substrate processing system 1 according to the exemplary embodiment, the plurality of first processing blocks 14 and the plurality of second processing blocks 15 may be arranged in a plurality of stages on both sides of the transfer block 13. The wafer W may be transferred between the first and second processing blocks 15 in each stage and the delivery module 114 by a single transfer device 132 provided in the transfer block 13.

The first processing block 14 is equipped with a plurality of liquid processing units 2.

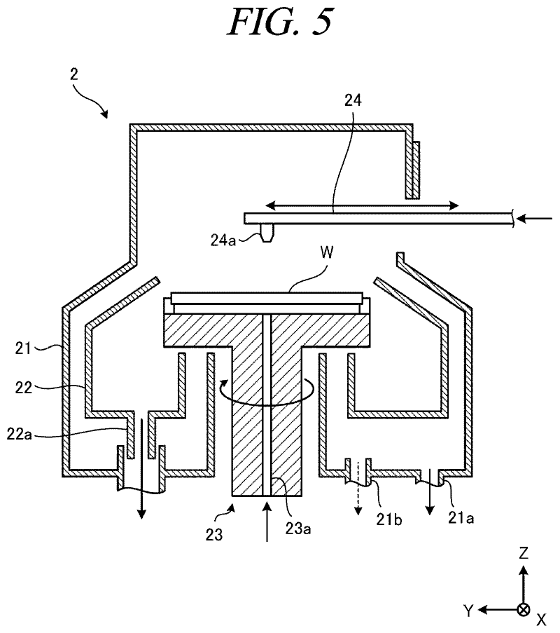

The liquid processing unit 2 is configured to perform a cleaning processing to clean an upper surface which is a pattern formation surface of the wafer W. Further, the liquid processing unit 2 is configured to perform a liquid film forming processing to form a liquid film by supplying isopropyl alcohol (IPA) (an example of a drying liquid) onto the upper surface of the wafer W after being subjected to the cleaning processing. A configuration of the liquid processing unit 2 will be described below with reference to FIG. 5.

The second processing block 15 is equipped with a plurality of measurement units 3, a plurality of drying units 4, and a plurality of supply units 6.

The measurement unit 3 is configured to measure a weight of the wafer W. More specifically, the measurement unit 3 measures a weight of the wafer W before and after the liquid film forming processing. In the exemplary embodiment, the measurement unit 3 is placed on the drying unit 4 (see FIG. 2).

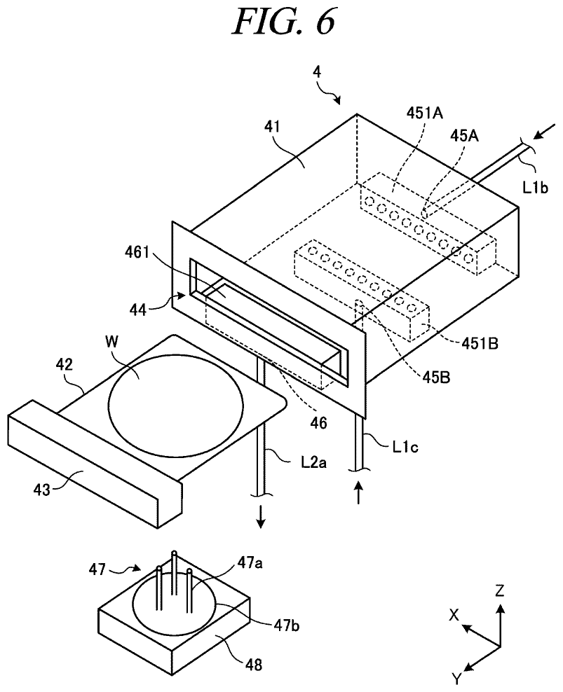

The drying unit 4 is configured to perform a supercritical drying processing on the wafer W after being subjected to the liquid film forming processing. More specifically, the drying unit 4 is configured to dry the wafer W after being subjected to the liquid film forming processing by bringing the wafer W into contact with a processing fluid in a supercritical state (hereinafter, referred to as “supercritical fluid”). A configuration of the drying unit 4 will be described with reference to FIG. 6.

The supply unit 6 is configured to supply the processing fluid to the drying unit 4. More specifically, the supply unit 6 is equipped with a supply device group including a flowmeter, a flow rate controller, a back pressure valve and a heater, and a housing accommodating therein the supply device group. In the present exemplary embodiment, the supply unit 6 supplies CO₂ as the supercritical fluid to the drying unit 4.

Further, as shown in FIG. 2, the measurement unit 3 and the drying unit 4 are arranged in the vertical direction. For example, the measurement unit 3 is arranged on the drying unit 4. The measurement unit 3 may be arranged under the drying unit 4. An installation area of the second processing block 15 is reduced since the measurement unit 3 and the drying unit 4 are arranged in the vertical direction.

The substrate processing system 1 is equipped with a control device 7. The control device 7 is, for example, a computer, and includes a controller 71 and a storage 72.

The controller 71 includes: a microcomputer having a CPU (Central Processing Unit), a ROM (Read Only Memory), a RAM (Random Access Memory) and an input/output port, and various types of circuits. The CPU of the microcomputer reads out and executes a program stored in the ROM and thus implements controls over the transfer devices 113 and 132, the liquid processing unit 2, the drying unit 4, and the supply unit 6.

Further, the program is stored in a computer-readable recording medium and may be installed to the storage 72 of the control device 7 from the recording medium. The computer-readable recording medium may be, for example, a hard disk (HD), a flexible disk (FD), a compact disk (CD), a magnet optical disk (MO), a memory card, or the like.

The storage 72 may be, for example, a semiconductor memory device such as a RAM or a flash memory, or a storage device such as a hard disk or an optical disk.

### <Sequence of Substrate Processings>

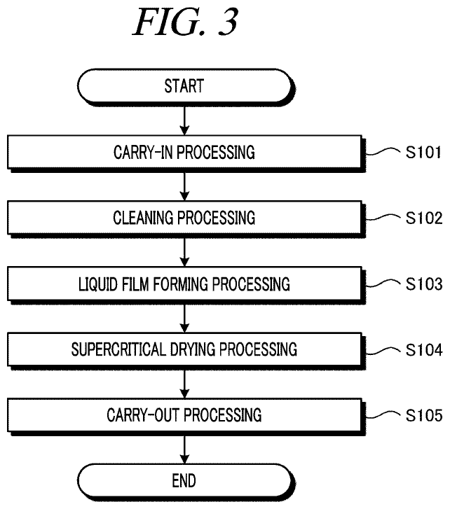

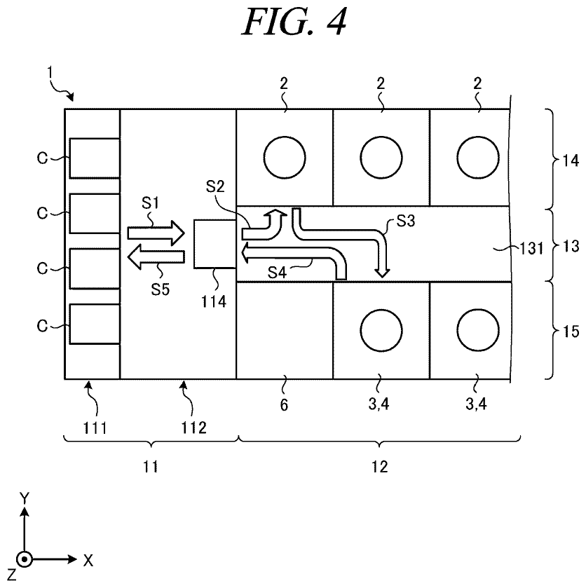

Hereinafter, a sequence of transferring the wafer W and a sequence of a series of substrate processings performed in the substrate processing system 1 will be described with reference to FIG. 3 and FIG. 4. FIG. 3 is a flowchart illustrating the sequence of the series of substrate processings performed in the substrate processing system 1 according to the present exemplary embodiment. FIG. 4 is a schematic diagram showing the sequence of transferring the wafer W. The series of substrate processings shown in FIG. 3 is performed under the control of the controller 71.

As shown in FIG. 3, the substrate processing system 1 performs a carry-in processing (process S101). In the carry-in processing, the transfer device 113 (see FIG. 1) takes the wafer W out of the carrier C and places the wafer W in the delivery module 114 (see process S1 in FIG. 4).

Then, the transfer device 132 (see FIG. 1) takes the wafer W out of the delivery module 114 and carries the wafer W into the liquid processing unit 2 (see process S2 in FIG. 4).

Thereafter, in the substrate processing system 1, the liquid processing unit 2 performs the cleaning processing (process S102). The liquid processing unit 2 removes particles and a natural oxide film from the upper surface of the wafer W by supplying various processing liquids onto the upper surface which is the pattern formation surface of the wafer W.

Subsequently, in the substrate processing system 1, the liquid processing unit 2 performs the liquid film forming processing (process S103). The liquid processing unit 2 accumulates the IPA on the upper surface of the wafer W by supplying the IPA in a liquid state onto the upper surface of the wafer W after being subjected to the cleaning processing.

The transfer device 132 transfers the wafer W after being subjected to the liquid film forming processing from the liquid processing unit 2 to the drying unit 4 (process S3 in FIG. 4).

Then, in the substrate processing system 1, the drying unit 4 starts the supercritical drying processing (process S104). In this supercritical drying processing, the drying unit 4 dries the wafer W with the liquid film formed thereon by bringing the wafer W into contact with the supercritical fluid. For example, after a predetermined period of drying time, the controller 71 ends the drying processing.

Thereafter, in the substrate processing system 1, a carry-out processing is performed (process S105). In the carry-out processing, the transfer device 132 takes the wafer W after being subjected to the supercritical drying processing out of the drying unit 4 and transfers the wafer W to the delivery module 114 (see process S4 in FIG. 4). Subsequently, the transfer device 113 takes the wafer W after being subjected to the supercritical drying processing out of the delivery module 114 and transfers the wafer W to the carrier C (see process S5 in FIG. 4). Upon the completion of the carry-out processing, the series of substrate processings of the single wafer W is ended.

### <Configuration of Liquid Processing Unit>

Hereinafter, a configuration of the liquid processing unit 2 will be described with reference to FIG. 5. FIG. 5 is a schematic diagram illustrating an example configuration of the liquid processing unit 2 according to the present exemplary embodiment. The liquid processing unit 2 is configured as a single-wafer cleaning apparatus configured to clean the wafers W individually by, for example, spin cleaning.

As shown in FIG. 5, the liquid processing unit 2 holds the wafer W substantially horizontally by a wafer holding mechanism 23 provided within an outer chamber 21 forming therein a processing space, and rotates the wafer W by rotating the wafer holding mechanism 23 around a vertical axis. Further, the liquid processing unit 2 allows a nozzle arm 24 to enter above the wafer W being rotated, and performs the cleaning processing on the upper surface of the wafer W by supplying a chemical liquid and a rinse liquid in a predetermined order from a chemical liquid nozzle 24a provided at a tip end portion of the nozzle arm 24.

Furthermore, in the liquid processing unit 2, a chemical liquid supply path 23a is formed within the wafer holding mechanism 23. A lower surface of the wafer W is also cleaned with the chemical liquid or the rinse liquid supplied from this chemical liquid supply path 23a.

In the cleaning processing, particles and organic contaminants are removed with, for example, an SC1 solution (a mixed solution of ammonia and oxygenated water) as an alkaline chemical liquid. Then, rinse cleaning is performed with deionized water (hereinafter, referred to as “DIW”) as the rinse liquid. Subsequently, a natural oxide film is removed with diluted hydrofluoric acid (hereinafter, referred to as “DHF”) as an acidic chemical liquid, and rinse cleaning is performed with DIW.

The above-described chemical liquids are received by the outer chamber 21 or an inner cup 22 disposed within the outer chamber 21, and then drained from a drain port 21a provided at a bottom of the outer chamber 21 and a drain port 22a provided at a bottom of the inner cup 22. Further, an atmosphere within the outer chamber 21 is exhausted through an exhaust port 21b provided at the bottom of the outer chamber 21.

The liquid film forming processing is performed after the rinse processing in the cleaning processing. More specifically, the liquid processing unit 2 supplies the IPA to the upper surface and the lower surface of the wafer W while rotating the wafer holding mechanism 23. Accordingly, the DIW remaining on the both surfaces of the wafer W is replaced with the IPA. Thereafter, the liquid processing unit 2 stops the rotation of the wafer holding mechanism 23 gently.

The wafer W after being subjected to the liquid film forming processing is delivered, while having a liquid film of the IPA formed on the upper surface thereof, to the transfer device 132 by a non-illustrated delivery mechanism provided in the wafer holding mechanism 23. Then, the wafer W is carried out of the liquid processing unit 2. The liquid film formed on the wafer W suppresses pattern collapse caused by evaporation of the liquid on the upper surface of the wafer W during the transfer or the carry-in of the wafer W from the liquid processing unit 2 into the drying unit 4 or the measurement unit 3.

### <Configuration of Drying Unit>

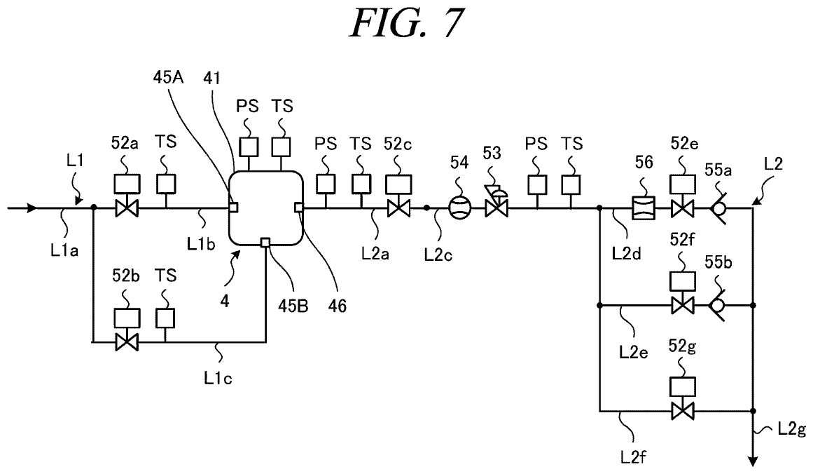

Hereinafter, a configuration of the drying unit 4 will be described with reference to FIG. 6 and FIG. 7. FIG. 6 is a schematic diagram illustrating an example configuration of the drying unit 4 according to the present exemplary embodiment. FIG. 7 is a schematic diagram illustrating an example pipe arrangement of the drying unit 4 according to the present exemplary embodiment.

The drying unit 4 performs the above-described supercritical drying processing. The drying unit 4 dries the wafer W by replacing the IPA accumulated on the wafer W with the supercritical fluid. The supercritical fluid is a fluid that is placed under a temperature higher than a critical temperature and a pressure higher than a critical pressure, and is a fluid in which the liquid and gas phases are indistinguishable. By replacing the IPA with the supercritical fluid, it is possible to suppress appearance of a liquid-gas interface in a concave-convex pattern of the wafer W. As a result, it is possible to suppress generation of surface tension and thus possible to suppress the collapse of the concave-convex pattern. The supercritical fluid is, for example, CO₂.

As shown in FIG. 6, the drying unit 4 is equipped with a processing chamber 41, a holder 42, a lid 43, a lifter 47, and a weight sensor 48. The processing chamber 41 accommodates therein the wafer W on which the IPA is accumulated. The processing chamber 41 is equipped with an opening 44 for carry-in and carry-out of the wafer W, supply ports 45A and 45B connected to a supply line L1 to be described later, and a discharge port 46 connected to a discharge line L2 to be described later.

The holder 42 holds the wafer W in the horizontal posture. The lid 43 supports the holder 42. The lid 43 is connected to a movement mechanism (not shown), and moved horizontally between a processing position located inside the processing chamber and a first delivery position located outside the processing chamber by the movement mechanism. When the lid 43 is moved to the processing position, the holder 42 is disposed inside the processing chamber 41 and the lid 43 closes the opening 44 of the processing chamber 41.

The lifter 28 is equipped with a plurality of lifter pins 47a, a support 47b which is connected to lower ends of the plurality of lifter pins 47a to support the plurality of lifter pins 47a.

The lifter 47 is raised and lowered by a lift driving mechanism (not shown). More specifically, the lifter 47 is raised and lowered between the first delivery position in which wafer W is delivered between the transfer device 132 and the holder 42, a second delivery position which is located above the first delivery position and in which the wafer W is transferred between the transfer device 132 and the measurement unit 3, and a standby position located, for example, between the first and second delivery positions. The standby position is set to avoid interference with the lid 43 and the holder 42.

The weight sensor 48 is, for example, a load cell, and measures the weight of the wafer W supported by the lifter 47. More specifically, the weight sensor 48 measures the weight of the wafer W before and after the drying processing.

The supply port 45A is connected to a side surface of the processing chamber 41 on a side opposite to the opening 44. The supply port 45B is connected to a bottom surface of the processing chamber 41. The discharge port 46 is connected to a lower side of the opening 44. Although two supply ports 45A and 45B and one discharge port 46 are illustrated in FIG. 6 and FIG. 7, the number of supply ports 45A and 45B and the number of discharge ports 46, and positions thereof are not particularly limited thereto.

The processing chamber 41 is internally equipped with supply headers 451A and 451B and a discharge header 461. Each of the supply headers 451A and 451B and the discharge header 461 includes a large number of openings formed therein.

The supply header 451A is connected to the supply port 45A and provided inside the processing chamber 41 to be adjacent to the side surface opposite to the opening 44. The large number of openings formed in the supply header 451A faces the opening 44.

The supply header 451B is connected to the supply port 45B and provided in a central portion of the bottom surface inside the processing chamber 41. The large number of apertures formed in the supply header 451B faces upwards.

The discharge header 461 is connected to the discharge port 46, and provided inside the processing chamber 41 to be adjacent to the side surface on the side of the opening 44 and to be below the opening 44. Further, the large number of apertures formed in the discharge header 461 faces the supply header 451A.

The supply headers 451A and 451B supply the supercritical fluid into the processing chamber 41. Also, the discharge header 461 discharges the mixed fluid containing the supercritical fluid and the IPA inside the processing chamber 41 to the outside.

As shown in FIG. 7, the drying unit 4 is connected to the supply line L1 for supplying the supercritical fluid to the drying unit 4 and the discharge line L2 for discharging the supercritical fluid and other fluids (e.g., the mixed fluid to be described below) from the drying unit 4. The supply line L1 connects a fluid source and the processing chamber 41. The supercritical fluid is supplied to the supply line L1 from the fluid source. The supply line L1 is equipped with a heater (not shown). The heater maintains the supercritical fluid supplied to the processing chamber 41 at a critical temperature or higher. The heater is provided, for example, over the entire supply line L1.

The supply line L1 includes a common line L1a, a distribution line L1b, and a boost line L1c. An upstream end of the common line L1a is connected to the fluid source, and a downstream end of the common line L1a is connected to the distribution line L1b and the boost line L1c. The distribution line L1b is connected to the supply port 45A, and the boost line L1c is connected to the supply port 45B.

The distribution line L1b is equipped with an opening/closing valve 52a and a temperature sensor TS. The opening/closing valve 52a opens and closes a fluid flow path. When the opening/closing valve 52a opens the fluid flow path, the supercritical fluid is supplied into the processing chamber 41 via the supply port 45A and the supply header 451A (see FIG. 6). Meanwhile, when the opening/closing valve 52a closes the fluid flow path, the supply of the supercritical fluid into the processing chamber 41 is stopped.

Similarly, the boost line L1c is equipped with an opening/closing valve 52b and a temperature sensor TS. The opening/closing valve 52b opens and closes the fluid flow path. When the opening/closing valve 52b opens the fluid flow path, the supercritical fluid is supplied into the processing chamber 41 via the supply port 45B and the supply header 451B (see FIG. 6). Meanwhile, when the opening/closing valve 52b closes the fluid flow path, the supply of the supercritical fluid into the processing chamber 41 is stopped.

Although the distribution line L1b and the boost line L1c are separately provided in the present exemplary embodiment, they may be integrated with each other.

The discharge line L2 includes, for example, an opening/closing line L2a, a first common line L2c, a first intermediate line L2d, a second intermediate line L2e, a third intermediate line L2f, and a second common line L2g.

The opening/closing line L2a extends from the discharge port 46 of the processing chamber 41 to an upstream end of the first common line L2c. The opening/closing line L2a is equipped with an opening/closing valve 52c, a temperature sensor TS, and a pressure sensor PS. The opening/closing valve 52c opens and closes the fluid flow path. When the opening/closing valve 52c opens the fluid flow path, the fluid inside the processing chamber 41 is discharged to the outside of the substrate processing system 1 via the discharge header 461 (see FIG. 6) and the discharge port 46. Meanwhile, when the opening/closing valve 52c closes the fluid flow path, the discharge of the fluid from the processing chamber 41 is stopped.

The first common line L2c is provided with a pressure-reducing valve 53, a flowmeter 54, a temperature sensor TS, and a pressure sensor PS. The pressure-reducing valve 53 reduces a pressure of the fluid on a downstream side of the pressure-reducing valve 53 to be lower than a pressure of the fluid on an upstream side of the pressure-reducing valve 53. The pressure on the upstream side of the pressure-reducing valve 53 is, for example, 4 MPa to 18 MPa, and the pressure on the downstream side of the pressure-reducing valve 53 is, for example, 0.1 MPa to 0.5 MPa. The flowmeter 54 measures a flow rate of the fluid before the pressure is reduced, but may measure a flow rate of the fluid after the pressure is reduced.

Each of the first intermediate line L2d, the second intermediate line L2e, and the third intermediate line L2f extends from a downstream end of the first common line L2c to an upstream end of the second common line L2g.

The first intermediate line L2d is equipped with an opening/closing valve 52e, a check valve 55a, and an orifice 56. The opening/closing valve 52e opens and closes the fluid flow path. When the opening/closing valve 52e opens the fluid flow path, the fluid inside the processing chamber 41 passes through the opening/closing valve 52e and is discharged to the outside of the substrate processing system 1. Meanwhile, when the opening/closing valve 52e closes the fluid flow path, the discharge of the fluid through the first intermediate line L2d is stopped. The check valve 55a suppresses backflow of the fluid.

Similarly, the second intermediate line L2e is equipped with an opening/closing valve 52f and a check valve 55b. The opening/closing valve 52f opens and closes the fluid flow path. When the opening/closing valve 52f opens the fluid flow path, the fluid inside the processing chamber 41 passes through the opening/closing valve 52f and is discharged to the outside of the substrate processing system 1. Meanwhile, when the opening/closing valve 52f closes the fluid flow path, the discharge of the fluid through the second intermediate line L2e is stopped. The check valve 55b suppresses backflow of the fluid.

The third intermediate line L2f is equipped with an opening/closing valve 52g. The opening/closing valve 52g opens and closes the fluid flow path. When the opening/closing valve 52g opens the fluid flow path, the fluid inside the processing chamber 41 passes through the opening/closing valve 52g and is discharged to the outside of the substrate processing system 1. Meanwhile, when the opening/closing valve 52g closes the fluid flow path, the discharge of the fluid through the third intermediate line L2f is stopped.

The first intermediate line L2d, the second intermediate line L2e, and the third intermediate line L2f are separately provided in the present exemplary embodiment, but may be integrated with each other. However, in the former case, it is possible to finely control a discharge flow rate of the fluid by discharging the fluid through a plurality of opening/closing valves 52e, 52f and 52g.

### <Supercritical Drying Method>

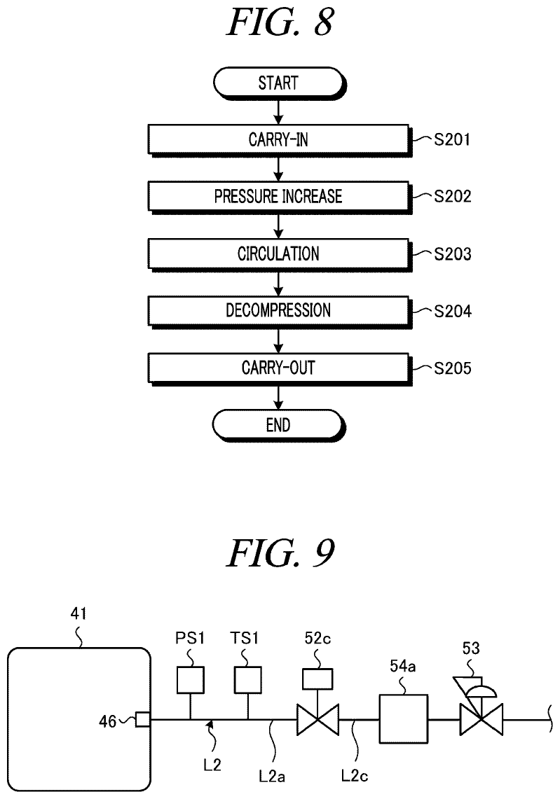

Hereinafter, a sequence of supercritical drying processings will be described with reference to FIG. 8. FIG. 8 is a flowchart illustrating the sequence of the supercritical drying processings performed in the substrate processing system 1 according to the present exemplary embodiment. Processes S201 to S205 shown in FIG. 8 are performed under the control of the control device 7.

First, in the process S201, a transfer device (not shown) carries the wafer W, on which the IPA is accumulated, into the drying unit 4. The holder 42 receives the wafer W from the transfer device and horizontally holds the wafer W with the liquid film of the IPA facing upwards. The wafer W is accommodated in the processing chamber 41, and the lid 43 closes the opening 44 of the processing chamber 41.

Subsequently, in the process S202, the supply line L1 supplies the supercritical fluid into the processing chamber 41 through the supply port 45B and the supply header 451B and thus increases an internal pressure of the processing chamber 41. Herein, the supercritical fluid is supplied from below the wafer W so as to suppress disturbance of the IPA accumulated on the wafer W. The internal pressure of the processing chamber 41 is increased to a set pressure equal to or higher than the critical pressure. During this time, the discharge line L2 does not discharge the fluid inside the processing chamber 41.

Then, in the process S203, the supply line L1 supplies the supercritical fluid into the processing chamber 41 through the supply port 45A and the supply header 451A, and the discharge line L2 discharges the fluid inside the processing chamber 41 and circulates the supercritical fluid above the wafer W. The IPA dissolved in the supercritical fluid is discharged to the outside of the processing chamber 41, and the IPA accumulated on the wafer W is replaced with the supercritical fluid, and, thus, the wafer W is dried. Also, in the process S203, the internal pressure of the processing chamber 41 is maintained at the set pressure.

Thereafter, in the process S204, the supply line L1 stops the supply of the supercritical fluid into the processing chamber 41, and the discharge line L2 discharges the fluid inside the processing chamber 41, and, thus, the inside of the processing chamber 41 is decompressed. The internal pressure of the processing chamber 41 is reduced to about atmospheric pressure (0.1 MPa). Then, the lid 23 opens the opening 44 of the processing chamber 41, and the wafer W is taken out of the processing chamber 41.

Finally, in the process S205, the transfer device 132 receives the wafer W from the holder 42 and carries the received wafer W to the outside of the drying unit 4.

Hereinafter, a configuration of the discharge line L2 according to the present exemplary embodiment will be described in more detail with reference to FIG. 9. FIG. 9 is a schematic diagram illustrating an example configuration of the discharge line L2 according to the present exemplary embodiment. In the process S203, the discharge line L2 discharges the mixed fluid containing the supercritical fluid and the IPA dissolved in the supercritical fluid from the inside of the processing chamber 41.

As described above, the discharge line L2 includes the opening/closing line L2a and the first common line L2c. The opening/closing line L2a is equipped with a pressure sensor PS1, a temperature sensor TS1, and an opening/closing valve 52c in this order from an upstream side to a downstream side. Further, the first common line L2c is equipped with a density detector 54a and a pressure-reducing valve 53 in this order from the upstream side to the downstream side.

The density detector 54a is configured to detect a density of the fluid flowing through the discharge line L2. More specifically, the density detector 54a detects a density of the mixed fluid (hereinafter, referred to as “mixed fluid density D₁”) flowing through the discharge line L2. Also, the density detector 54a detects a density of the supercritical fluid (hereinafter, referred to as “reference density D₂”) flowing through the discharge line L2. As a concentration of the IPA in the mixed fluid increases, the mixed fluid density D₁ increases. Therefore, the mixed fluid density D₁ includes information about the concentration of the IPA in the mixed fluid.

The density detector 54a is provided, for example, on the upstream side of the pressure-reducing valve 53. Almost no pressure loss occurs on the upstream side of the pressure-reducing valve 53. Further, there is almost no temperature change caused by the pressure loss. Therefore, the mixed fluid density D₁ and the reference density D₂ can be detected at the same temperature and pressure as the internal temperature and pressure of the processing chamber 41. Thus, the density of the mixed fluid inside the processing chamber 41 and the density of the supercritical fluid can be detected more accurately.

The density detector 54a may be any density detector as long as it can detect the density of the mixed fluid and the density of the supercritical fluid. As the density detector 54a, a density meter for high temperature and high pressure may be used. For example, a gamma ray density meter or the like that measures a density with gamma rays may be used. The density detector 54a detects the mixed fluid density D₁ at every unit time. Similarly, the density detector 54a detects the reference density D₂ at every unit time. The detection results are output to the control device 7.

Although only one density detector 54a is illustrated in FIG. 9, the number of density detectors is not limited to one and may be two or more.

A pressure detector 57 is configured to detect a pressure of the fluid flowing through the discharge line L2. More specifically, the pressure detector 57 detects a pressure of the mixed fluid flowing through the discharge line L2 (hereinafter, referred to as “first pressure P_{A}”). Also, the pressure detector 57 detects a pressure of the supercritical fluid flowing through the discharge line L2 (hereinafter, referred to as “second pressure P_{B}”). The pressure detector 57 detects the first pressure P_{A} at every unit time. Also, the pressure detector 57 detects the second pressure P_{B} at every unit time. The detection results are output to the control device 7.

The pressure detector 57 includes, for example, a pressure sensor PS1 as shown in FIG. 9. The pressure sensor PS1 is provided, for example, on a downstream side of the processing chamber 41 and an upstream side of the opening/closing valve 52c. Although only one pressure sensor PS1 is illustrated in FIG. 9, the number of pressure sensors PS is not limited to one and may be two or more.

A temperature detector 58 is configured to detect a temperature of the fluid flowing through the discharge line L2. More specifically, the temperature detector 58 detects a temperature of the mixed fluid flowing through the discharge line L2 (hereinafter, referred to as “first temperature T_{A}”). Also, the temperature detector 58 detects a temperature of the supercritical fluid flowing through the discharge line L2 (hereinafter, referred to as “second temperature T_{B}”). The temperature detector 58 detects the first temperature T_{A} at every unit time. Also, the temperature detector 58 detects the second temperature T_{B} at every unit time. The detection results are output to the control device 7.

The temperature detector 58 includes, for example, a temperature sensor TS1 as shown in FIG. 9. The temperature sensor TS1 is provided, for example, on a downstream side of the processing chamber 41 and an upstream side of the opening/closing valve 52c. Although only one temperature sensor TS1 is illustrated in FIG. 9, the number of temperature sensors TS is not limited to one and may be two or more.

### <Function of Control Device>

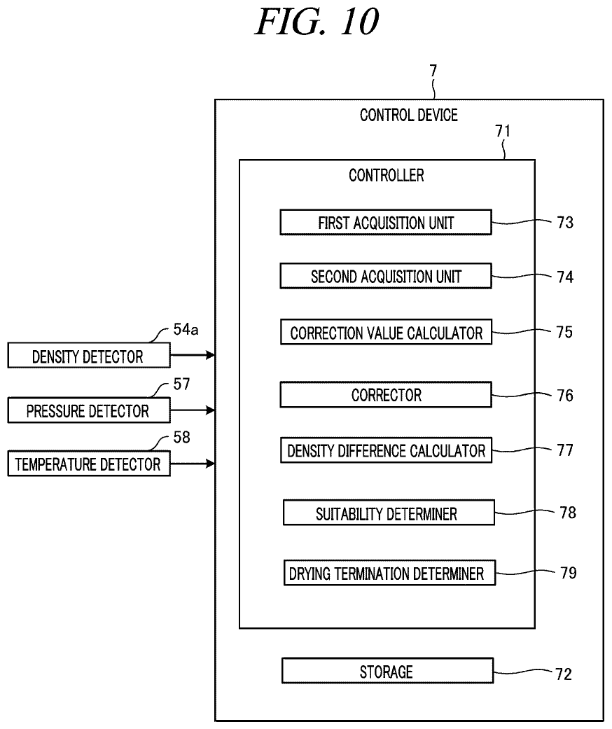

Hereinafter, a function of the control device 7 will be described. FIG. 10 illustrates an example configuration of the control device 7 according to the present exemplary embodiment as a functional block. Each functional block illustrated in FIG. 10 is conceptual and does not necessarily have to be physically configured as illustrated. It is possible to configure all or portion of each functional block to be functionally or physically distributed/integrated in any unit. All or any portion in each processing function performed in each function block may be implemented by a program executed by a CPU, or may be implemented as hardware by wired logic.

The control device 7 includes, for example, the controller 71 and the storage 72. For example, the controller 71 is equipped with a first acquisition unit 73, a second acquisition unit 74, a correction value calculator 75, a corrector 76, a density difference calculator 77, a suitability determiner 78, and a drying termination determiner 79.

The storage 72 stores time-dependent change data of the reference density D₂ detected by the density detector 54a, time-dependent change data of the second pressure P_{B} detected by the pressure detector 57, and time-dependent change data of the second temperature T_{B} detected by the temperature detector 58. Each of these time-dependent change data is stored in the storage 72 for each of the plurality of drying units 4.

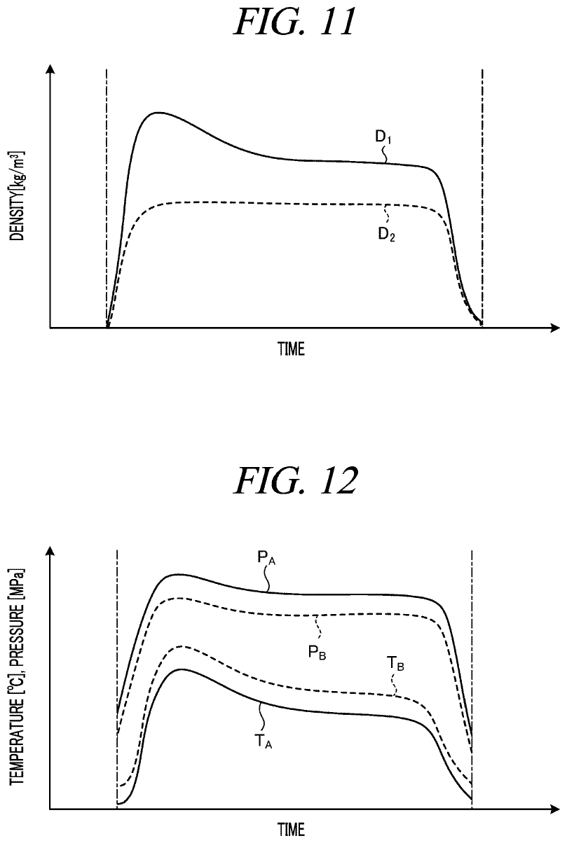

First, time-dependent change data of the mixed fluid density D₁ and the reference density D₂ will be described with reference to FIG. 11. FIG. 11 shows an example of time-dependent changes in the mixed fluid density D₁ and the reference density D₂. In FIG. 11, auxiliary lines indicated by dashed-dotted lines represent the period during which the process S203 in FIG. 8 is performed.

The mixed fluid density D₁ is acquired by detecting the density of the fluid flowing through the discharge line L2, i.e., the density of the mixed fluid, during the supercritical drying processing of the wafer W with the accumulated IPA by the density detector 54a. The reference density D₂ is acquired by detecting the density of the fluid flowing through the discharge line L2, i.e., the density of the supercritical fluid, during the supercritical drying processing of the wafer W without accumulated liquid IPA by the density detector 54a.

The time-dependent change data of the mixed fluid density D₁ is indicated by a solid line in FIG. 11. When the opening/closing valve 52c opens the flow path in the process S203 in FIG. 8, the mixed fluid containing the supercritical fluid and the IPA dissolved in the supercritical fluid is discharged from the processing chamber 41 to the discharge line L2. Accordingly, the mixed fluid density D₁ increases with time and reaches a peak value. The peak value of the mixed fluid density D₁ and the time to reach the peak value depend on the amount of IPA previously accumulated on the wafer W. As the amount of accumulated liquid increases, the peak value of the mixed fluid density D₁ increases and the time for the mixed fluid density D₁ to reach the peak value increases.

After the mixed fluid density D₁ reaches the peak value, as the replacement of the IPA with the supercritical fluid progresses on the upper surface of the wafer W, the concentration of the IPA in the mixed fluid discharged from the processing chamber 41 to the discharge line L2 decreases. As a result, the mixed fluid density D₁ decreases. The decrease in the mixed fluid density D₁ represents a degree to which the replacement of the IPA with the supercritical fluid progresses. In other words, the decrease in the mixed fluid density D₁ represents a degree to which the drying of the wafer W progresses. As the drying of the wafer W progresses, the amount of IPA remaining on the wafer W decreases and the rate of decrease in the mixed fluid density D₁ slows down.

The first acquisition unit 73 acquires the mixed fluid density D₁ by the density detector 54a. More specifically, the first acquisition unit 73 acquires time-dependent change data of the mixed fluid density D₁ detected by the density detector 54a during the supercritical drying processing (process S104 in FIG. 3).

The second acquisition unit 74 acquires the reference density D₂ by the density detector 54a. More specifically, the second acquisition unit 74 acquires time-dependent change data of the reference density D₂ detected by the density detector 54a during a supercritical drying processing performed in advance on the wafer W for reference density detection, specifically, the wafer W without accumulated IPA.

The supercritical drying processing for the wafer W without accumulated IPA is performed as a preliminary processing before the wafer W with the accumulated IPA (product wafer) is processed with the supercritical fluid. The time-dependent change data of the reference density D₂ acquired by the second acquisition unit 74 is stored in advance in the storage 72.

Further, the supercritical drying processing performed on the wafer W for reference density detection is performed under the same drying conditions as the supercritical drying processing (process S104 in FIG. 3) performed on the product wafer W. Furthermore, the time-dependent change data acquired by the first acquisition unit 73 and the second acquisition unit 74 is stored in the storage 72 for each of the plurality of drying units 4.

The correction value calculator 75 calculates a correction value for correcting the reference density D₂ based on the detection results from the temperature detector 58 and the pressure detector 57. The corrector 76 corrects the reference density D₂ based on the correction value calculated by the correction value calculator 75.

Herein, the processings performed by the correction value calculator 75 and the corrector 76 according to the present exemplary embodiment will be described with reference to FIG. 12 to FIG. 15. FIG. 12 shows an example of time-dependent changes in the first pressure P_{A}, the first temperature T_{A}, the second pressure P_{B}, and the second temperature T_{B}. In FIG. 12, auxiliary lines indicated by dashed-dotted lines represent the period during which the process S203 in FIG. 8 is performed. The vertical axis represents a pressure MPa and a temperature° C.

In FIG. 12, the first pressure P_{A} indicates a pressure of the mixed fluid detected by the pressure detector 57 during the supercritical drying processing for the wafer W with the accumulated IPA. The first temperature T_{A} indicates a temperature of the mixed fluid detected by the temperature detector 58 during the same processing. The first pressure P_{A} and the first temperature T_{A} are detected during the same supercritical drying processing for the same wafer W.

The second pressure P_{B} indicates a pressure of the supercritical fluid detected by the pressure detector 57 during the supercritical drying processing for the wafer W without accumulated IPA. The second temperature T_{B} indicates a temperature of the supercritical fluid detected by the temperature detector 58 during the same processing. The second pressure P_{B} and the second temperature T_{B} are detected during the same supercritical drying processing for the same wafer W.

The pressure detector 57 and the temperature detector 58 detect the first pressure P_{A} and the first temperature T_{A} during the supercritical drying processing (process S104 in FIG. 3). Time-dependent change data of the detected first pressure P_{A} and first temperature T_{A} is acquired by the controller 71 and stored in the storage 72. Also, the pressure detector 57 and the temperature detector 58 detect the second pressure P_{B} and the second temperature T_{B} during the supercritical drying processing performed in advance on the wafer W for reference density detection. Time-dependent change data of the detected second pressure P_{B} and second temperature T_{B} is acquired by the controller 71 and stored in advance in the storage 72.

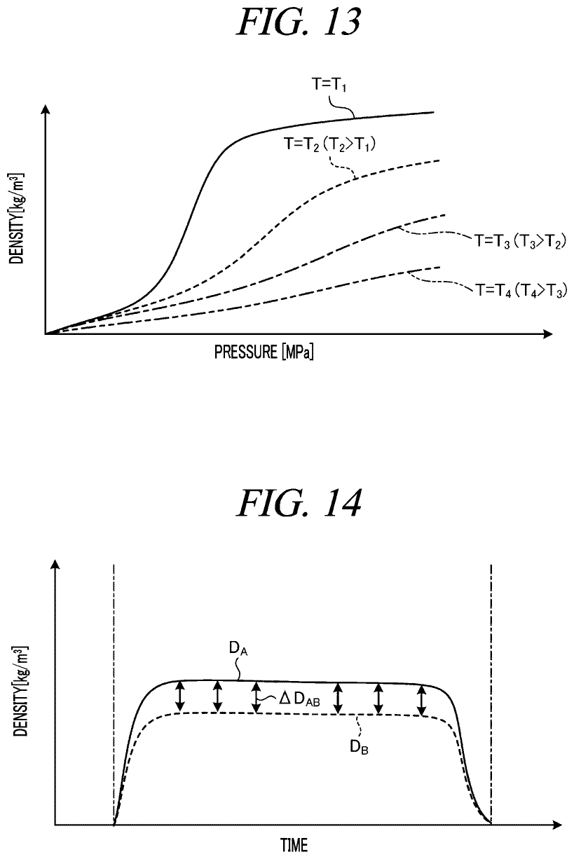

FIG. 13 is a graph showing an example of a relationship of density, pressure, and temperature of a pure supercritical fluid. In FIG. 13, T represents a temperature of the supercritical fluid. A temperature T₁ is higher than a temperature T₂, the temperature T₂ is higher than a temperature T₃, and the temperature T₃ is higher than a temperature T₄. As shown in FIG. 13, at a constant pressure, the density decreases with increasing temperature. At a constant temperature, the density increases with increasing pressure. The relationship of density, pressure, and temperature of the supercritical fluid is determined in advance by an experiment and stored in the storage 72. The relationship may be stored in the form of an equation. The equation is generally referred to as a state equation.

The correction value calculator 75 calculates a density D_{A} of the mixed fluid (hereinafter, referred to as “first density D_{A}”) based on the first pressure P_{A} and the first temperature T_{A} and according to the state equation. Also, the correction value calculator 75 acquires, from the storage 72, the second pressure P_{B} and the second temperature T_{B} detected at the same time (at each time interval from the start of the process S203 in FIG. 8) as the detection of the first pressure P_{A} and the first temperature T_{A} in the same drying unit 4 where the first pressure P_{A} and the first temperature T_{A} are detected. The correction value calculator 75 calculates a density D_{B} of the mixed fluid (hereinafter, referred to as “second density D_{B}”) based on the second pressure P_{B} and the second temperature T_{B} acquired from the storage 72 and according to the state equation. Then, the correction value calculator 75 calculates, as the correction value ΔD_{AB}, a difference D_{A}−D_{B} between the calculated first density D_{A} and the calculated second density D_{B}. The correction value ΔD_{AB} is calculated at every unit time.

FIG. 14 shows an example of time-dependent changes in the first density D_{A} and the second density D_{B}. In FIG. 14, auxiliary lines indicated by dashed-dotted lines represent the period during which the process S203 in FIG. 8 is performed.

The correction value ΔD_{AB} represents a density difference of the supercritical fluid caused by differences in pressure and temperature in the processing chamber 41 between the supercritical drying processing performed on the product wafer W (process S104 in FIG. 3) and the supercritical drying processing performed on the wafer W for reference density detection.

Herein, the differences in pressure and temperature refer to differences in pressures and temperatures in the processing chamber 41 during the supercritical drying processing for the product wafer W and during the supercritical drying processing for the wafer W for reference density detection, compared at each time interval from the start of the process S203 in FIG. 8. Since the temperature and the pressure can fluctuate slightly during the supercritical drying processing, the differences may occur at each time interval from the start of supercritical fluid supply. That is, the correction value ΔD_{AB} can fluctuate at each time interval from the start of supercritical fluid supply.

The corrector 76 corrects the reference density D₂ based on the correction value ΔD_{AB} calculated by the correction value calculator 75. More specifically, the corrector 76 adds the correction value ΔD_{AB} calculated by the correction value calculator 75 to the reference density D₂ acquired from the storage 72 to calculate a corrected reference density (hereinafter, referred to as “corrected reference density D₃”). The corrected reference density D₃ is calculated at every unit time.

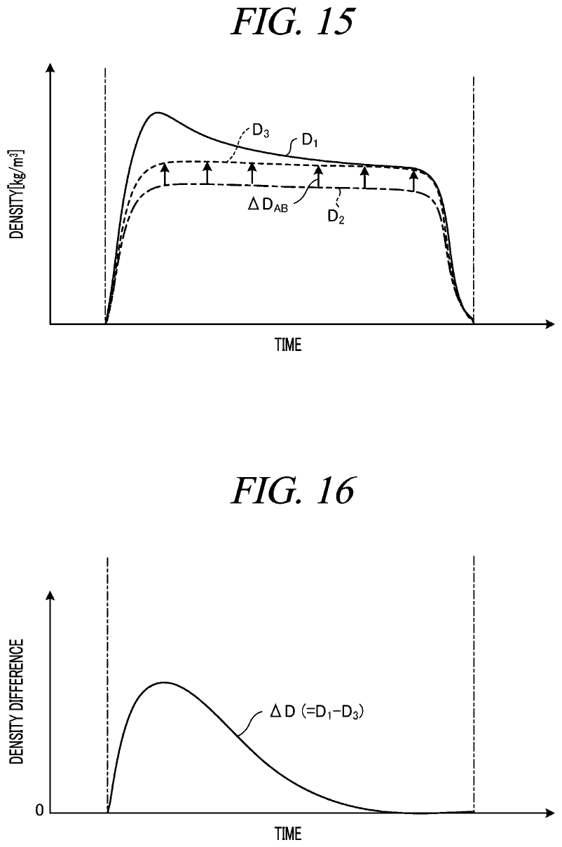

FIG. 15 shows an example of changes in the mixed fluid density D₁, the reference density D₂, and the corrected reference density D₃. Also, the corrector 76 performs correction using the calculated correction value ΔD_{AB} based on the pressure and temperature data detected in the same drying unit 4 where the reference density D₂ is detected.

The density difference calculator 77 calculates a density difference ΔD between the mixed fluid density D₁ and the corrected reference density D₃. The density difference ΔD is calculated at every unit time.

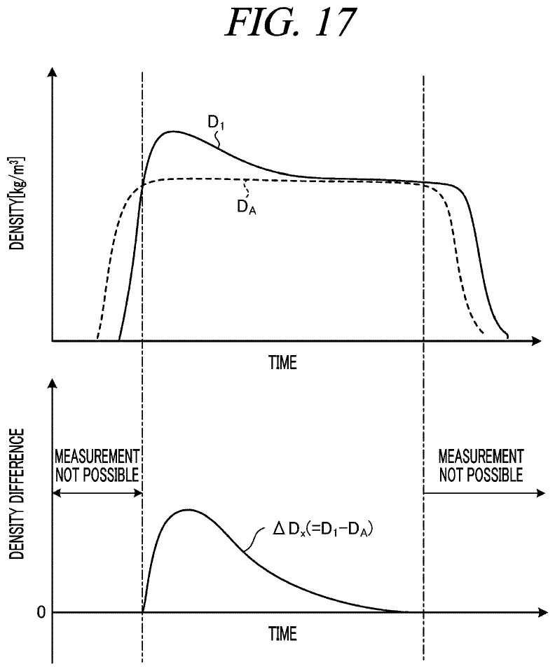

FIG. 16 shows an example of time-dependent changes in the density difference ΔD between the mixed fluid density D₁ and the corrected reference density D₃. As shown in FIG. 16, the density difference ΔD typically reaches a peak once and then gradually decreases, and becomes zero (0) when the drying is completed.

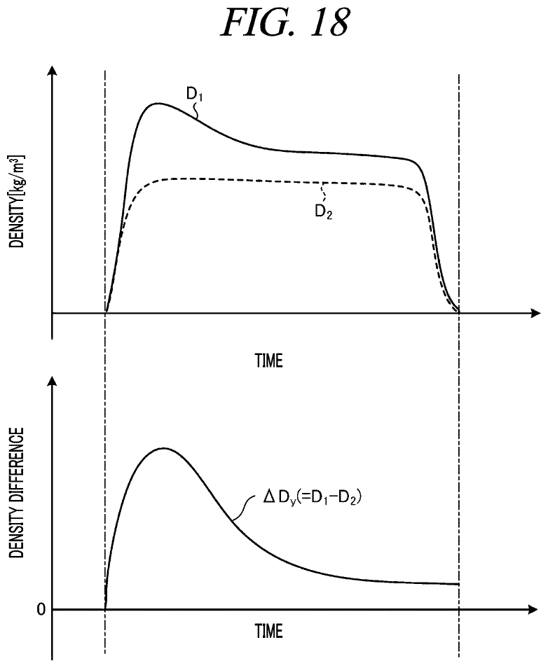

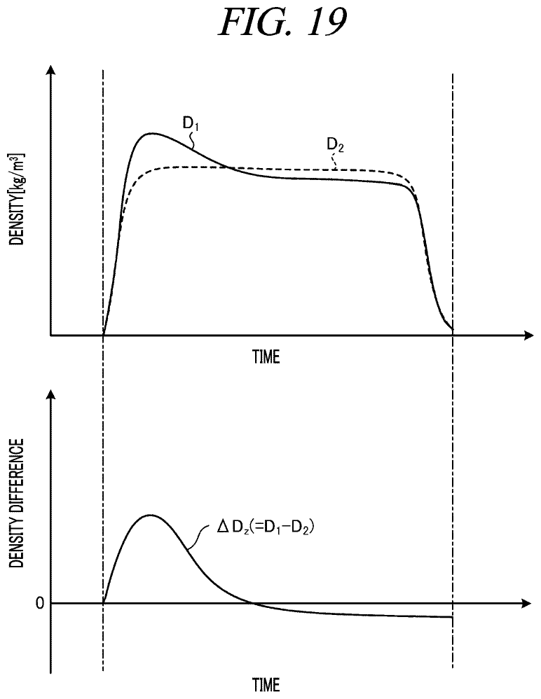

Hereinafter, features of time-dependent change data of the density difference ΔD calculated by the density difference calculator 77 according to the present exemplary embodiment will be described with reference to FIG. 17 to FIG. 19. FIG. 17 shows an example (first comparative example) of time-dependent changes in density difference ΔDₓ between the mixed fluid density D₁ and the first density D_{A}. FIG. 18 shows an example (second comparative example) of time-dependent changes in density difference ΔD_{y} between the mixed fluid density D₁ and the reference density D₂. FIG. 19 shows another example (third comparative example) of time-dependent changes in density difference ΔD_{z} between the mixed fluid density D₁ and the reference density D₂.

FIG. 17 illustrates an example where the density difference ΔDₓ is calculated from the difference between the mixed fluid density D₁ and the first density D_{A}. That is, FIG. 17 illustrates an example where the density difference ΔDₓ is calculated from a difference between the mixed fluid density D₁ detected by the density detector 54a and the density of the supercritical fluid calculated based on the pressure and the temperature detected by the pressure detector 57 and the temperature detector 58. In FIG. 17, auxiliary lines indicated by dashed-dotted lines represent the period during which the density difference is calculated by the density difference calculator 77 in the supercritical drying processing.

As shown in FIG. 17, when the density difference ΔDₓ is calculated from the difference between the mixed fluid density D₁ and the first density D_{A}, it may not be possible to accurately calculate the density difference ΔDₓ in situations where the pressure and the temperature in the processing chamber change rapidly. This is due to different response times between the density detector 54a and the pressure and temperature detectors 57 and 58. More specifically, significant differences may occur in the timing of rises and falls in the time-dependent change data of the mixed fluid density D₁ and the first density D_{A}. Therefore, in the process S203 of FIG. 8, except for periods when the pressure and the temperature in the processing chamber 41 are stable, it is difficult to calculate the density difference ΔDₓ.

Meanwhile, as described above, the density difference calculator 77 calculates the density difference ΔD from the difference between the mixed fluid density D₁ and the reference density D₂ (specifically, the corrected reference density D₃), both detected by the density detector 54a. Therefore, unlike the first comparative example, the density difference calculator 77 can calculate the density difference ΔD without being affected by the difference in response time between the density detector 54a and the pressure detector 57/the temperature detector 58. Therefore, as shown in FIG. 16, the substrate processing system 1 according to the present exemplary embodiment can calculate the density difference ΔD throughout the entire period of the process S203 in FIG. 8.

Further, in the substrate processing system 1 according to the present exemplary embodiment, even under different drying conditions, the timing of rises in the time-dependent change data of the density difference ΔD can be standardized at the start of the process S203 in FIG. 8. Therefore, it becomes easy to compare the time-dependent change data of the density difference ΔD calculated under the different drying conditions.

FIG. 18 illustrates an example where the density difference ΔD_{y} is calculated from the difference between the mixed fluid density D₁ and the reference density D₂. FIG. 19 illustrates another example where the density difference ΔD_{z} is calculated from the difference between the mixed fluid density D₁ and the reference density D₂. That is, FIG. 18 and FIG. 19 show examples where the density difference ΔD is calculated from the difference between the mixed fluid density and the density of the supercritical fluid, both detected by the density detector 54a. In FIG. 18 and FIG. 19, auxiliary lines indicated by dashed-dotted lines represent the period during which the density difference is calculated by the density difference calculator 77 in the supercritical drying processing.

As shown in FIG. 18 and FIG. 19, when the density differences ΔD_{y} and ΔD_{z} are simply calculated from the difference between the mixed fluid density D₁ and the reference density D₂, errors may occur due to the differences in pressure and temperature in the processing chamber when the mixed fluid density D₁ and the reference density D₂ are acquired during the supercritical drying processing. As also shown in FIG. 13, the density of the fluid containing the supercritical fluid changes when the pressure or the temperature changes. Therefore, for example, as shown in FIG. 18, even if the supercritical drying processing is properly completed, the density difference ΔD_{y} may not become zero (0). Further, as shown in FIG. 19, the density difference ΔD_{z} may become a negative value. Thus, it may not be possible to properly monitor the supercritical drying processing.

Meanwhile, the density difference calculator 77 according to the present exemplary embodiment corrects the reference density D₂ detected by the density detector 54a based on the above-described correction value ΔD_{AB}, and then calculates the density difference ΔD based on the corrected reference density D₃, i.e., the reference density D₂ obtained after being corrected. Therefore, as shown in FIG. 16, even when there are differences in pressure and temperature in the processing chamber 41 during data acquisition, it is possible to accurately calculate the density difference ΔD.

Therefore, in the substrate processing system 1 according to the present exemplary embodiment, it is possible to accurately compare the time-dependent change data of the density difference ΔD calculated under the drying conditions with different pressures and temperatures in the processing chamber 41.

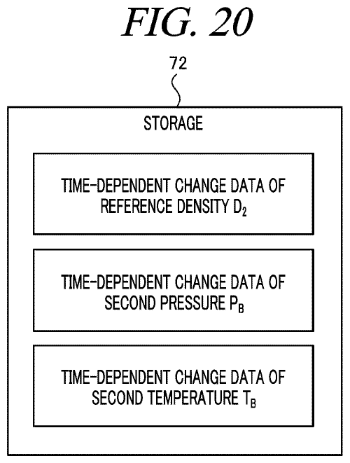

Hereinafter, time-dependent change data stored in advance in the storage 72 will be described with reference to FIG. 20. FIG. 20 shows an example of the time-dependent change data stored in the storage 72 according to the present exemplary embodiment. The substrate processing system 1 performs in advance the supercritical drying processing on the wafer W for reference density detection, i.e., the wafer W without accumulated IPA. In the process S203 of the supercritical drying processing shown in FIG. 8, the density detector 54a detects the reference density D₂ at every unit time. Also, the pressure detector 57 detects the second pressure P_{B} at every unit time. Further, the temperature detector 58 detects the second temperature T_{B} at every unit time.

Time-dependent change data of the detected reference density D₂ is acquired by the second acquisition unit 74 and stored in the storage 72. Also, time-dependent change data of the second pressure P_{B} and time-dependent change data of the second temperature T_{B} are acquired by the controller 71 and stored in the storage 72. Further, the time-dependent change data is stored in the storage 72 for each of the plurality of drying units 4.

The suitability determiner 78 determines whether the supercritical drying processing is suitable based on the time-dependent change data of the density difference ΔD calculated by the density difference calculator 77. Processings performed by the suitability determiner 78 will be described in detail below.

The drying termination determiner 79 determines the termination of the drying of the wafer W based on the time-dependent change data of the density difference ΔD calculated by the density difference calculator 77. Processings performed by the drying termination determiner 79 will be described in detail below.

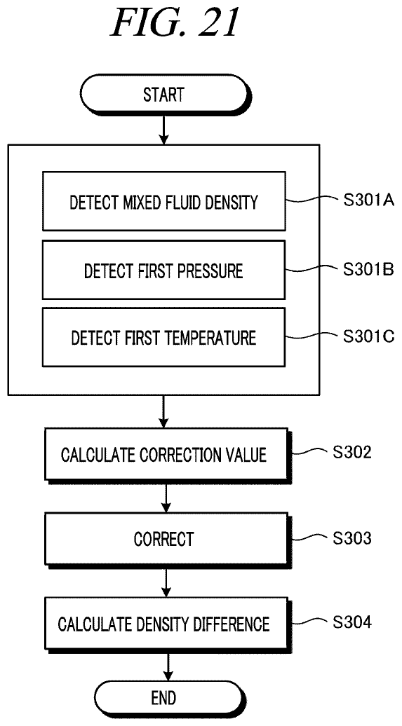

Hereinafter, a sequence of processings to calculate the density difference ΔD performed in the controller 71 will be described with reference to FIG. 21. FIG. 21 is a flowchart illustrating a sequence of a series of density difference calculation processings performed in the controller 71 according to the present exemplary embodiment. Further, each of the following processings is performed at every unit time throughout the entire period of the process S203 of the supercritical drying processing shown in FIG. 8.

First, the density detector 54a detects the mixed fluid density D₁ at every unit time (process S301A). Also, the pressure detector 57 detects the first pressure P_{A} at every unit time (process S301B). Further, the temperature detector 58 detects the first temperature T_{A} at every unit time (process S301C). Time-dependent change data of the detected mixed fluid density D₁, first pressure P_{A} and first temperature T_{A} are input to the controller 71.

Then, the correction value calculator 75 calculates the first density D_{A} at every unit time based on the first pressure P_{A} acquired in the process S301B and the first temperature T_{A} acquired in the process S301C and according to the state equation. Further, the correction value calculator 75 calculates the second density D_{B} at every unit time based on time-dependent change data of the second pressure P_{B} and second temperature T_{B} stored in advance in the storage 72 and according to the state equation. Furthermore, the correction value calculator 75 calculates the difference D_{A}−D_{B} between the first density D_{A} and the second density D_{B} as the correction value ΔD_{AB} (process S302). The correction value ΔD_{AB} is calculated at every unit time.

Thereafter, the corrector 76 corrects the reference density D₂ (process S303) based on the correction value ΔD_{AB} calculated by the correction value calculator 75 in the process S302. More specifically, the corrector 76 adds the correction value ΔD_{AB} calculated by the correction value calculator 75 to the reference density D₂ stored in advance in the storage 72 to calculate the corrected reference density D₃. The corrected reference density D₃ is calculated at every unit time.

Subsequently, the density difference calculator 77 calculates the density difference ΔD at every unit time from the difference between the mixed fluid density D₁ acquired by the first acquisition unit 73 in the process S301A and the corrected reference density D₃ calculated by the corrector 76 in the process S303 (process S304).

Although there has been described the example where the density difference ΔD is calculated at every unit time in the process S203 of the supercritical drying processing shown in FIG. 8, the density difference ΔD may be calculated after the supercritical drying processing. In this case, the value acquired in the process S301 is stored in the storage 72 and the calculation processing is performed as described above after the supercritical drying processing to calculate the density difference ΔD.

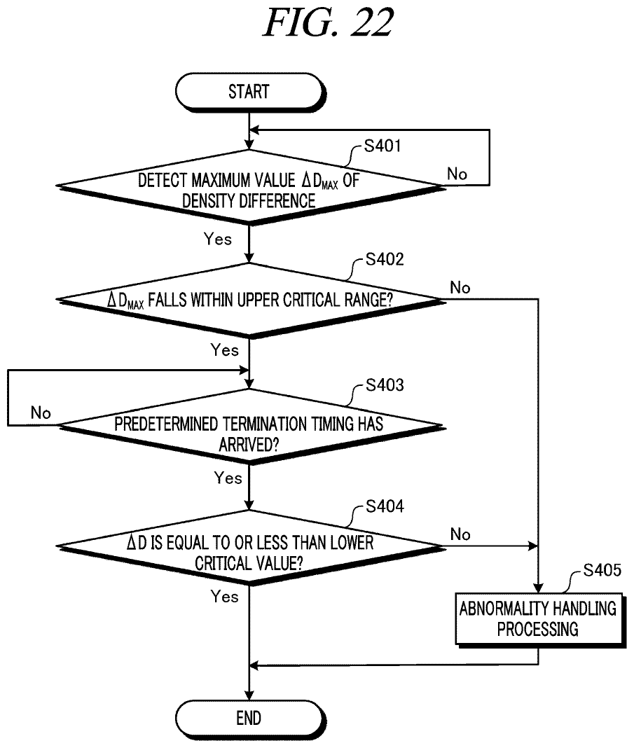

Hereinafter, processings performed by the suitability determiner 78 will be described with reference to FIG. 22. FIG. 22 is a flowchart illustrating a sequence of determination processings performed in the suitability determiner 78 according to the present exemplary embodiment. For example, the suitability determiner 78 determines whether the amount of IPA accumulated on the wafer W is appropriate based on the density difference ΔD calculated by the density difference calculator 77. Further, each of the following processings is performed at every unit time throughout the entire period of the process S203 of the supercritical drying processing shown in FIG. 8.

First, the suitability determiner 78 detects a maximum value of the density difference ΔD (hereinafter, referred to as “ΔD_{MAX}”) calculated by the density difference calculator 77 (process S401). For example, when the suitability determiner 78 detects that the density difference ΔD calculated by the density difference calculator 77 has decreased over a certain period, it identifies, as the ΔD_{MAX}, the largest density difference ΔD in the density differences ΔD calculated prior to the detection. If ΔD_{MAX} has not been detected (process S401: No), the suitability determiner 78 repeats the process S401.

Then, if the ΔD_{MAX} is detected in the process S401 (process S401: Yes), the suitability determiner 78 determines whether the detected ΔD_{MAX} falls within a predetermined upper critical range (process S402). The upper critical value is previously determined, for example, based on correlation information between the time-dependent change data of the density difference ΔD and the amount of IPA accumulated on the wafer W.

In the process S402, if the ΔD_{MAX} deviates from the upper critical range (process S402: No), the controller 71 performs an abnormality handling processing (process S405). For example, in the abnormality handling processing, the controller 71 may output, to an external device, information indicating that the amount of accumulated liquid is not appropriate. The information may include information, such as an identification number of the wafer W. Also, the controller 71 may turn on a warning lamp included in the substrate processing system 1 or display occurrence of abnormality on a monitor to notify an operator of the occurrence of abnormality.

Further, in the abnormality handling processing, the controller 71 may prohibit the use of the liquid processing unit 2 that has performed the liquid film forming processing on the wafer W determined to have the inappropriate amount of accumulated liquid. Similarly, in the abnormality handling processing, the controller 71 may prohibit the use of the drying unit 4 that has performed the supercritical drying processing on the wafer W determined to have the inappropriate amount of accumulated liquid.

Subsequently, in the process S402, if the ΔD_{MAX} falls within the upper critical range (process S402: Yes), the suitability determiner 78 determines whether a predetermined termination timing of determination has arrived (process S403). If the termination timing of determination has not arrived (process S403: No), the suitability determiner 78 repeats the process S403.

Then, in the process S403, if the termination timing of determination has arrived (process S403: Yes), the suitability determiner 78 determines whether the density difference ΔD calculated by the density difference calculator 77 is equal to or less than a predetermined lower critical value (process S404).

In the process S404, if the density difference ΔD is not equal to or less than the lower critical value (process S404: No), the controller 71 performs the abnormality handling processing (process S405). For example, in the abnormality handling processing, the controller 71 may output, to an external device, information indicating that the determination result is NG (No Good). The information may include information, such as an identification number of the wafer W. Also, the controller 71 may turn on a warning lamp included in the substrate processing system 1 or display the occurrence of abnormality on a monitor to notify an operator of the occurrence of abnormality.

In the process S404, if the density difference ΔD is equal to or less than the lower critical value (process S404: Yes), the suitability determiner 78 terminates the determination processing.

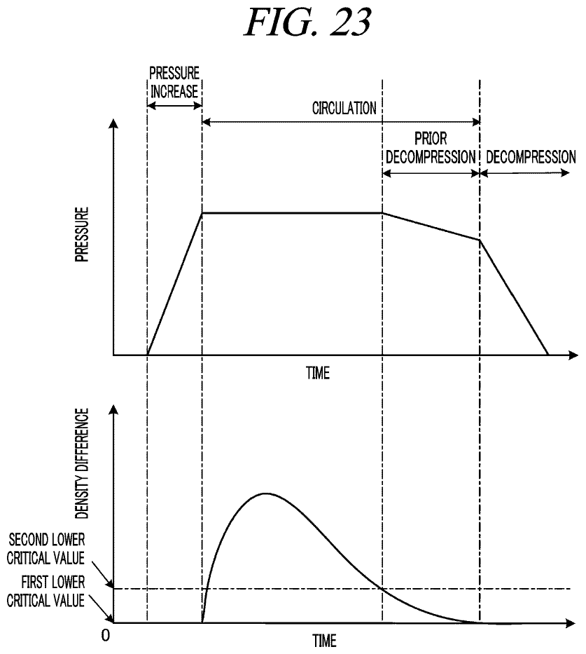

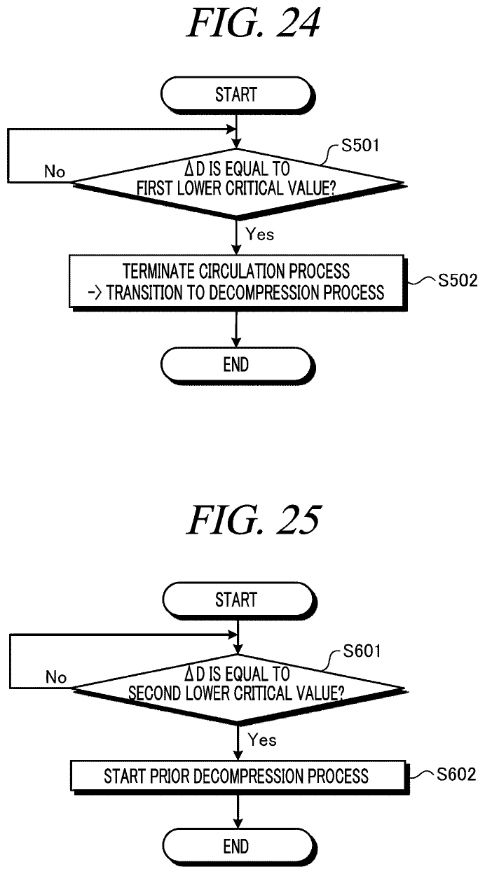

Hereinafter, processings performed by the drying termination determiner 79 will be described with reference to FIG. 23 and FIG. 24. FIG. 23 shows a relationship of the density difference ΔD between the mixed fluid density D₁ and the corrected reference density D₃ and the pressure in the processing chamber in the processes S201 to S203 in FIG. 8. FIG. 24 is a flowchart illustrating a sequence of determination processings performed in the drying termination determiner 79 according to the present exemplary embodiment.

The drying termination determiner 79 determines to terminate the drying of wafer W based on the density difference ΔD calculated by the density difference calculator 77. Also, each of the following processings is performed at every unit time in a period during which the density difference ΔD decreases in the process S203 of the supercritical drying processing shown in FIG. 8. For example, the drying termination determiner 79 may start the determination processing when it detects that the density difference ΔD calculated by the density difference calculator 77 has decreased over a certain period.

The drying termination determiner 79 determines whether the density difference ΔD calculated by the density difference calculator 77 is equal to or less than a predetermined first lower critical value (process S501). In the process S501, if the density difference ΔD is not equal to or less than the first lower critical value (process S501: No), the drying termination determiner 79 repeats the process S501.

In the process S501, if the density difference ΔD is equal to or less than the first lower critical value (process S501: Yes), the drying termination determiner 79 terminates the determination processing by stopping the circulation processing of the process S203 and starting the decompression processing of the process S204 (process S502) as shown in FIG. 23.

Hereinafter, an example of a control processing performed by the controller 71 will be described with reference to FIG. 23 and FIG. 25. As shown in FIG. 23, the substrate processing system 1 may perform a prior decompression processing under the control of the controller 71 in the process S203 of FIG. 8. The prior decompression processing is a processing to decompress the inside of the processing chamber 41 prior to the circulation processing of the process S203. For example, in the prior decompression processing, the supercritical fluid may be discharged to the outside of the processing chamber 41 at the discharge flow rate greater than the supply flow rate while the supercritical fluid is supplied into the processing chamber 41. The prior decompression processing is continued until the circulation processing is terminated. Then, the decompression processing of the process S204 is started continuously after the prior decompression processing.

The controller 71 may control a start timing of the prior decompression processing based on the density difference ΔD calculated by the density difference calculator 77. Further, each of the following processings is performed at every unit time in a period during which the density difference ΔD decreases in the process S203 of the supercritical drying processing shown in FIG. 8. For example, the controller 71 may start a series of control processings when it detects that the density difference ΔD calculated by the density difference calculator 77 has decreased over a certain period.

The controller 71 determines whether the density difference ΔD calculated by the density difference calculator 77 is equal to or less than a predetermined second lower critical value (process S601). In the process S601, if the density difference ΔD is not equal to or less than the second lower critical value (process S601: No), the drying termination determiner 79 repeats the process S601.

In the process S601, if the density difference ΔD is equal to or less than the second lower critical value (process S601: Yes), the controller 71 starts the prior decompression processing (process S602).

By performing the prior decompression processing, it is possible to start the decompression of the processing chamber 41 even before the density difference ΔD reaches zero (0) as the drying progresses. Therefore, it is possible to reduce a time required for the supercritical drying of the wafer W.

According to the above-described exemplary embodiments of the present disclosure, it is possible to accurately calculate the density difference between the density of the mixed fluid and the density of the supercritical fluid.

The exemplary embodiments disclosed herein are illustrative in all aspects and do not limit the present disclosure. In fact, the above exemplary embodiments can be embodied in various forms. Further, the above-described exemplary embodiments may be omitted, substituted, or changed in various forms without departing from the scope and spirit of the appended claims.
(1) A substrate processing apparatus, including:
a processing chamber configured to perform a drying processing on a substrate by supplying a supercritical fluid into the processing chamber and replacing a drying liquid accumulated on the substrate with the supercritical fluid;
a discharge line configured to discharge a fluid from an inside of the processing chamber, the fluid being the supercritical fluid or a mixed fluid containing the supercritical fluid and the drying liquid;
a density detector configured to detect a density of the fluid flowing through the discharge line;
a temperature detector configured to detect a temperature of the fluid flowing through the discharge line;
a pressure detector configured to detect a pressure of the fluid flowing through the discharge line; and
a controller,
wherein the controller includes:
a first acquisition unit configured to acquire a mixed fluid density, which is a density of the mixed fluid, by the density detector;
a second acquisition unit configured to acquire a reference density, which is a density of the supercritical fluid, by the density detector;
a correction value calculator configured to calculate a correction value for correcting the reference density based on detection results from the temperature detector and the pressure detector;
a corrector configured to correct the reference density based on the correction value calculated by the correction value calculator; and
a density difference calculator configured to calculate a density difference, which is a difference between the mixed fluid density acquired by the first acquisition unit and the reference density corrected by the corrector.
(2) The substrate processing apparatus described in (1),
wherein the correction value calculator calculates the correction value based on a first temperature which is a temperature of the mixed fluid detected by the temperature detector, a second temperature which is a temperature of the supercritical fluid detected by the temperature detector, a first pressure which is a pressure of the mixed fluid detected by the pressure detector, and a second pressure which is a pressure of the supercritical fluid detected by the pressure detector.
(3) The substrate processing apparatus described in (2),
wherein the correction value calculator calculates a first density, which is the density of the mixed fluid, based on the first temperature and the first pressure and a second density, which is the density of the supercritical fluid, based on the second temperature and the second pressure, and calculates, as the correction value, a difference between the first density and the second density.
(4) The substrate processing apparatus described in any one of (1) to (3), further including:
multiple drying units each including the processing chamber, the discharge line, the density detector, the temperature detector, and the pressure detector,
wherein the correction value calculator calculates the correction value for each of the multiple drying units.
(5) The substrate processing apparatus described in any one of (1) to (4),
wherein the drying processing includes:
a pressure increasing process of increasing a pressure in the processing chamber to a given supercritical pressure by supplying the supercritical fluid into the processing chamber in a state where the substrate is accommodated in the processing chamber;
a circulation process of discharging, after the pressure increasing process, the mixed fluid through the discharge line while supplying the supercritical fluid into the processing chamber; and
a decompression process of decompressing, after the circulation process, the inside of the processing chamber by stopping the supplying of the supercritical fluid into the processing chamber and discharging the mixed fluid through the discharge line, and
the controller is configured to monitor the density difference throughout an entire period from a time when the circulation processing is started to a time when the circulation processing is terminated.
(6) The substrate processing apparatus described in (5),
wherein the drying processing includes a prior decompression process of decompressing, before the circulation process is terminated, the inside of the processing chamber, and
the controller is configured to control a start timing of the prior decompression process based on time-dependent change data of the density difference calculated by the density difference calculator.
(7) The substrate processing apparatus described in any one of (1) to (6),
wherein the controller further includes a suitability determiner configured to determine whether the drying processing is suitable based on time-dependent change data of the density difference calculated by the density difference calculator.
(8) The substrate processing apparatus described in any one of (1) to (7),
wherein the drying processing includes a prior decompression process of decompressing, before the circulation process is terminated, the inside of the processing chamber, and
the controller is configured to control a start timing of the prior decompression process based on time-dependent change data of the density difference calculated by the density difference calculator.
(9) A substrate processing method performed by a substrate processing apparatus including: a processing chamber configured to perform a drying processing on a substrate by supplying a supercritical fluid into the processing chamber and replacing a drying liquid accumulated on the substrate with the supercritical fluid; a discharge line configured to discharge a fluid from an inside of the processing chamber, the fluid being the supercritical fluid or a mixed fluid containing the supercritical fluid and the drying liquid; a density detector configured to detect a density of the fluid flowing through the discharge line; a temperature detector configured to detect a temperature of the fluid flowing through the discharge line; and a pressure detector configured to detect a pressure of the fluid flowing through the discharge line, the substrate processing method including:
acquiring a mixed fluid density, which is a density of the mixed fluid, by the density detector;
acquiring a reference density, which is a density of the supercritical fluid, by the density detector;
calculating a correction value for correcting the reference density based on detection results from the temperature detector and the pressure detector;
correcting the reference density based on the correction value calculated in the calculating of the correction value; and
calculating a density difference, which is a difference between the mixed fluid density and the reference density corrected in the correcting of the reference density.

According to the present disclosure, the density difference between the density of the mixed fluid containing the supercritical fluid and the drying liquid and the density of the supercritical fluid can be calculated accurately.

From the foregoing, it will be appreciated that various exemplary embodiments of the present disclosure have been described herein for purposes of illustration and various changes can be made without departing from the scope and spirit of the present disclosure. Accordingly, various exemplary embodiments described herein are not intended to be limiting, and the true scope and spirit are indicated by the following claims.

We claim:

1. A substrate processing apparatus, comprising:
a processing chamber configured to perform drying processing on a substrate by supplying a supercritical fluid into the processing chamber and replacing a drying liquid accumulated on the substrate with the supercritical fluid;
a discharge line configured to discharge a fluid from an inside of the processing chamber, the fluid being the supercritical fluid or a mixed fluid containing the supercritical fluid and the drying liquid;
a density detector configured to detect a density of the fluid flowing through the discharge line;
a temperature detector configured to detect a temperature of the fluid flowing through the discharge line;
a pressure detector configured to detect a pressure of the fluid flowing through the discharge line; and
processing circuitry configured to:
acquire a mixed fluid density, which is a density of the mixed fluid, detected by the density detector;
acquire a reference density, which is a density of the supercritical fluid, detected by the density detector;
calculate a correction value for correcting the reference density based on detection results from the temperature detector and the pressure detector;
correct the reference density based on the correction value; and
calculate a density difference, which is a difference between the mixed fluid density and the corrected reference density.

2. The substrate processing apparatus of claim 1, wherein the processing circuitry is configured to calculate the correction value based on a first temperature which is a temperature of the mixed fluid detected by the temperature detector, a second temperature which is a temperature of the supercritical fluid detected by the temperature detector, a first pressure which is a pressure of the mixed fluid detected by the pressure detector, and a second pressure which is a pressure of the supercritical fluid detected by the pressure detector.

3. The substrate processing apparatus of claim 2, wherein the processing circuitry is configured to:
calculate a first density, which is the density of the mixed fluid, based on the first temperature and the first pressure,
calculate a second density, which is the density of the supercritical fluid, based on the second temperature and the second pressure, and
calculate, as the correction value, a difference between the first density and the second density.

4. The substrate processing apparatus of claim 1, further comprising:
multiple drying units each including the processing chamber, the discharge line, the density detector, the temperature detector, and the pressure detector,
wherein the processing circuitry is configured to calculate the correction value for each of the multiple drying units.

5. The substrate processing apparatus of claim 1, wherein
the drying processing includes:
a pressure increasing process of increasing a pressure in the processing chamber to a given supercritical pressure by supplying the supercritical fluid into the processing chamber in a state where the substrate is accommodated in the processing chamber;
a circulation process of discharging, after the pressure increasing process, the mixed fluid through the discharge line while supplying the supercritical fluid into the processing chamber; and
a decompression process of decompressing, after the circulation process, the inside of the processing chamber by stopping the supplying of the supercritical fluid into the processing chamber and discharging the mixed fluid through the discharge line, and
the processing circuitry is configured to monitor the density difference throughout an entire period from a time when the circulation processing is started to a time when the circulation processing is terminated.

6. The substrate processing apparatus of claim 5, wherein
the drying processing includes a prior decompression process of decompressing, before the circulation process is terminated, the inside of the processing chamber, and
the processing circuitry is configured to control a start timing of the prior decompression process based on time-dependent change data of the density difference.

7. The substrate processing apparatus of claim 1, wherein the processing circuitry is configured to determine whether the drying processing is suitable based on time-dependent change data of the density difference.

8. The substrate processing apparatus of claim 1, wherein the processing circuitry is configured to determine termination of the drying processing on the substrate based on time-dependent change data of the density difference.

9. A method, comprising:
acquiring a mixed fluid density, which is a density of a mixed fluid containing a supercritical fluid and a drying liquid discharged from an inside of a processing chamber configured to perform drying processing on a substrate;
acquiring a reference density, which is a density of the supercritical fluid discharged from the inside of the processing chamber;
calculating a correction value for correcting the reference density based on temperature and pressure detection results;
correcting the reference density based on the correction value; and
calculating a density difference, which is a difference between the mixed fluid density and the corrected reference density.

10. The method according to claim 9, wherein calculating the correction value includes calculating the correction value based on a first temperature which is a temperature of the mixed fluid, a second temperature which is a temperature of the supercritical fluid, a first pressure which is a pressure of the mixed fluid, and a second pressure which is a pressure of the supercritical fluid.

11. The method according to claim 10, further comprising:
calculating a first density, which is the density of the mixed fluid, based on the first temperature and the first pressure,
calculating a second density, which is the density of the supercritical fluid, based on the second temperature and the second pressure, and
calculating, as the correction value, a difference between the first density and the second density.

12. The method according to claim 9, further comprising monitoring the density difference throughout an entire period from a time when a circulation processing of discharging, after a pressure increasing process of increasing a pressure in the processing chamber to a given supercritical pressure by supplying the supercritical fluid into the processing chamber in a state where the substrate is accommodated in the processing chamber, the mixed fluid while supplying the supercritical fluid into the processing chamber is started to a time when the circulation processing is terminated.

13. The method according to claim 12, further comprising controlling a start timing of a prior decompression process of decompressing, before the circulation process is terminated, the inside of the processing chamber based on time-dependent change data of the density difference.

14. The method according to claim 9, further comprising determining whether the drying processing is suitable based on time-dependent change data of the density difference.

15. The method according to claim 9, further comprising determining termination of the drying processing on the substrate based on time-dependent change data of the density difference.
